(19) United States
(12) Patent Application Publication
(10) Pub. No.: US 2025/0155513 A1
(43) Pub. Date: May 15, 2025

(54) MEASUREMENT SYSTEM AND METHOD FOR CALCULATING RESISTANCE OF INTERNAL SHORT CIRCUIT OF BATTERY AND METHOD FOR ESTABLISHING BATTERY REFERENCE SAMPLE

(71) Applicant: INDUSTRIAL TECHNOLOGY RESEARCH INSTITUTE, Hsinchu (TW)

(72) Inventors: Tai-Hua HSIAO, Hsinchu City (TW); Shih-Hao LIANG, New Taipei City (TW); Cheng-You HO, Changhua City (TW); Zong-Yan WU, Jiaoxi Township (TW); Yu-Hsiang HUNG, Hsinchu (TW)

(73) Assignee: INDUSTRIAL TECHNOLOGY RESEARCH INSTITUTE, Hsinchu (TW)

(21) Appl. No.: 18/589,158

(22) Filed: Feb. 27, 2024

(30) Foreign Application Priority Data
Nov. 14, 2023 (TW) 112143819

(51) Int. Cl. G01R 31/389; G01R 31/367; G01R 31/3842; G01R 31/52; H02J 7/00

(52) U.S. Cl. CPC G01R 31/389; G01R 31/367; G01R 31/3842; G01R 31/52; H02J 7/0047

(57) ABSTRACT

A method for calculating a resistance of an internal short circuit in a battery is provided, which includes the following steps. Multiple voltage-capacity curve samples of a battery under multiple stable current charging and/or discharging conditions are obtained. The charge and/or discharge data of the battery are measured, and the charge and/or discharge data at least includes a charging voltage sequence and a charging current sequence, and/or a discharge voltage sequence and a discharge current sequence. The charge and/or discharge data of the battery is compared with at least one reference curve in the voltage-capacity curve samples to determine whether the battery is charging and/or discharging normally. When the charge and/or discharge data of the battery deviates from the reference curve, a leakage current and a leakage resistance of the battery are calculated.

This application claims the benefit of Taiwan application Serial No. 112143819, filed Nov. 14, 2023, the disclosure of which is incorporated by reference herein in its entirety.

### TECHNICAL FIELD

The disclosure relates to a measurement system and a method for calculating a resistance of an internal short circuit of a battery and a method for establishing battery reference samples.

### BACKGROUND

In recent years, under the global net-zero emission trends, electric vehicles have become one of the important ways to achieve the goal of carbon neutrality. However, since fire accidents of electric vehicles have occurred frequently, battery safety testing of electric vehicles has become more important. In order to effectively manage battery performance and limit the danger caused by incorrect battery operation, the battery must be further connected to the battery management system to determine whether the battery is charging and discharging normally. Usually, an internal short circuit in the battery will cause a very large current in circuits instantaneously. The energy released by the large current may not only burn out the circuits and detonate sparks, but also cause the battery to over-discharge in a very short period of time, releasing a large amount of heat energy to increase battery temperature, thereby causing thermal runaway. Therefore, how to quickly and effectively detect battery abnormalities and avoid thermal runaway is a problem that the industry is trying to solve.

### SUMMARY

The present disclosure relates to a measurement system and a method for calculating a resistance of an internal short circuit in a battery and a method for establishing battery reference samples, which are configured to establish a battery model to simulate battery charging and/or discharging behaviors, using varying currents and stable currents to generate multiple voltage-capacity curve samples and determine whether the battery is abnormal based on the voltage-capacity curves, and calculate a leakage current and a leakage resistance.

According to one embodiment of the present disclosure, a method for calculating a resistance of an internal short circuit in a battery is provided, which includes the following steps. Multiple voltage-capacity curve samples of a battery under multiple stable current charging and/or discharging conditions are obtained. The charge and/or discharge data of the battery are measured, and the charge and/or discharge data at least includes a charging voltage sequence and a charging current sequence, and/or a discharge voltage sequence and a discharge current sequence. The charge and/or discharge data of the battery is compared with at least one reference curve in the voltage-capacity curve samples to determine whether the battery is charging or discharging normally. When the charge and/or discharge data of the battery deviates from the reference curve, a leakage current and a leakage resistance of the battery are calculated.

According to one embodiment of the present disclosure, a method for establishing reference samples of a battery is provided, including the following steps. A battery or a battery model is provided, and the battery model is used to simulate charging and/or discharging behaviors of the battery. The battery or the battery model is charged and discharged with a current. The current is changed at least once to obtain multiple voltage-capacity curves of the battery under multiple varying currents charging and/or discharging conditions. The voltage-capacity curves of the battery are grouped and evaluated based on the varying currents to obtain multiple voltage-capacity curve samples of the battery under multiple stable current charging or discharging conditions.

According to one embodiment of the present disclosure, a measurement system for calculating a resistance of an internal short circuit in a battery is provided, including a measurement module, a comparison module and a resistance calculation module. The measurement module is configured to measure charge and/or discharge data of a battery. The charge and/or discharge data at least include a charging voltage sequence and a charging current sequence and/or a discharge voltage sequence and a discharge current sequence. The reference sample module is configured for storing a plurality voltage-capacity curve samples of the battery under stable current charging and/or discharging conditions. The comparison module is configured to obtain multiple voltage-capacity curve samples of the battery under multiple stable current charge and/or discharge conditions, and compare the charge and/or discharge data of the battery with at least one reference curve of the voltage-capacity curve samples to determine whether the battery is charging and/or discharging normally. When the charge and/or discharge data of the battery deviates from the reference curve, the resistance calculation module calculates a leakage current and a leakage resistance of the battery.

### BRIEF DESCRIPTION OF THE DRAWINGS

FIG. 1 is a schematic diagram illustrating a method for calculating a resistance of an internal short circuit in a battery according to an embodiment of the present disclosure.

FIG. 2 is a schematic diagram of a battery measurement system according to an embodiment of the present disclosure.

FIG. 3A is a schematic diagram of a RC equivalent circuit of the battery model.

FIG. 3B is a schematic diagram of multiple voltage-capacity curve samples of the battery under multiple stable current discharge.

FIG. 4 is a schematic diagram of estimating the current difference based on the voltage difference of the battery under the same capacity.

FIG. 5 is a schematic diagram showing the deviation of battery voltage from a predetermined discharge reference curve.

FIG. 6 is a schematic diagram of a method for establishing a battery reference sample according to an embodiment of the present disclosure.

FIG. 7A is a schematic diagram of the voltage-capacity curves of the battery under various varying current discharging conditions in FIG. 6.

FIG. 7B is a schematic diagram of the voltage-capacity curve of the battery under various varying current charging conditions in FIG. 6.

FIG. 8A is a schematic diagram of discharging with multiple discharge currents or multiple varying currents, grouping and curve evaluation to obtain multiple voltage-capacity curve samples under multiple stable currents.

FIG. 8B is a schematic diagram of charging with multiple charging currents or multiple varying currents, grouping and curve evaluation to obtain multiple voltage-capacity curve samples under multiple stable currents.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

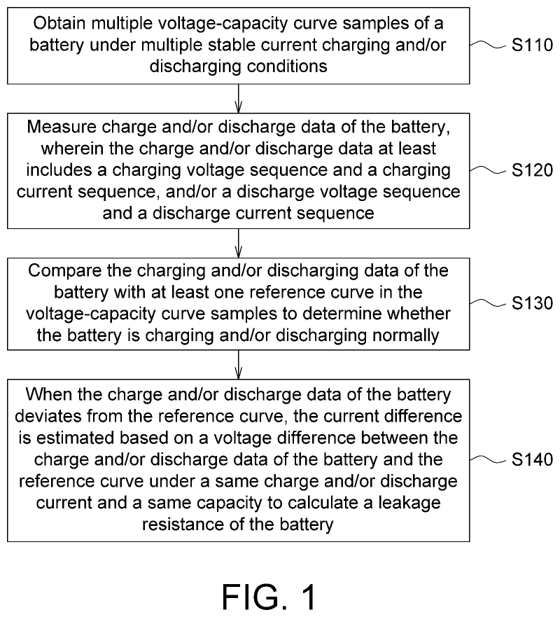

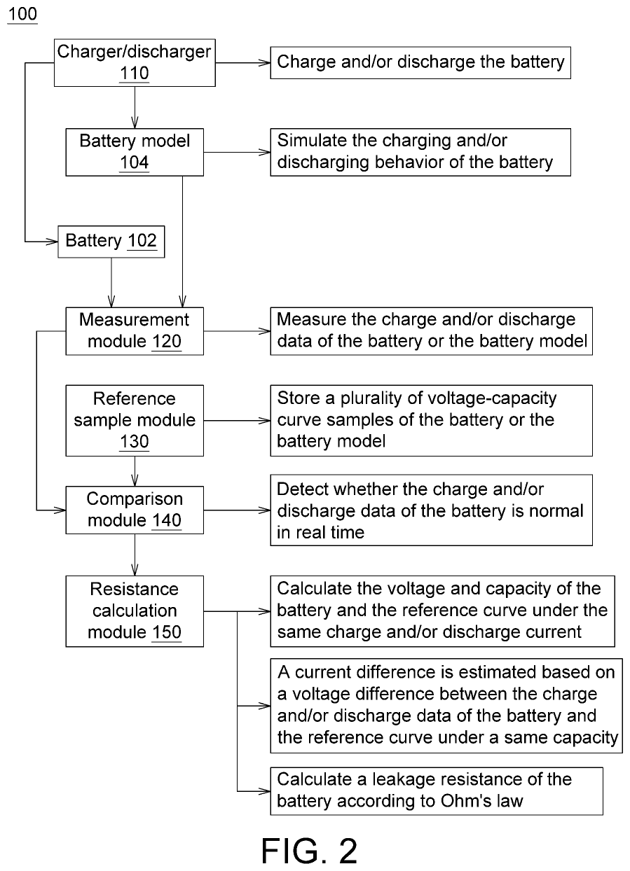

Referring to FIGS. 1 and 2. FIG. 1 is a schematic diagram of a method for calculating a resistance of an internal short circuit in the battery 102 according to an embodiment of the disclosure, and FIG. 2 is a battery measurement system 100 according to an embodiment of the disclosure. In one embodiment, the battery measurement system 100 can be used to measure the charge and/or discharge data of the battery 102 or a battery model 104, and can instantly calculate the leakage current and leakage resistance of the short circuit in the battery 102 to determine whether the battery 102 is damaged or abnormal.

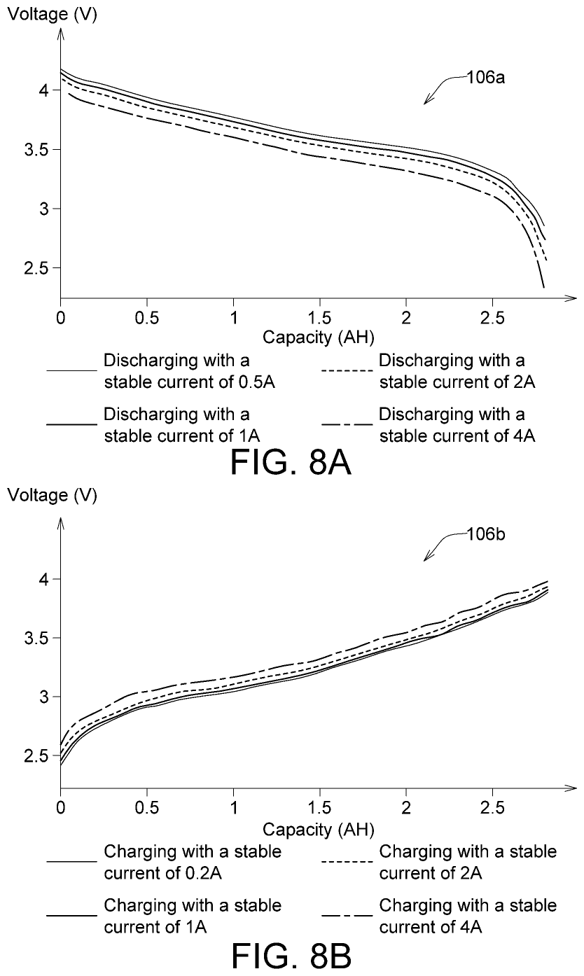

As shown in FIGS. 1 and 2, the method for calculating a resistance of an internal short circuit in the battery 102 includes the following steps. In step S110, multiple voltage-capacity curve samples 106a and 106b of the battery 102 under multiple stable current charging and/or discharging conditions are obtained (see FIGS. 8A and 8B). In step S120, the charge and/or discharge data of the battery 102 is measured. The charge and/or discharge data at least includes a charging voltage sequence and a charging current sequence, and/or a discharge voltage sequence and a discharge current sequence. In step S130, the charging and/or discharging data of the battery 102 is compared with at least one reference curve in the voltage-capacity curve samples 106a and 106b to determine whether the battery 102 is charging and/or discharging normally. In step S140, when the charge and/or discharge data of the battery 102 deviates from the reference curve, the current difference is estimated based on the voltage difference between the charge and/or discharge data of the battery 102 and the reference curve under a same charge and/or discharge current and a same capacity, to calculate a leakage resistance of the battery 102.

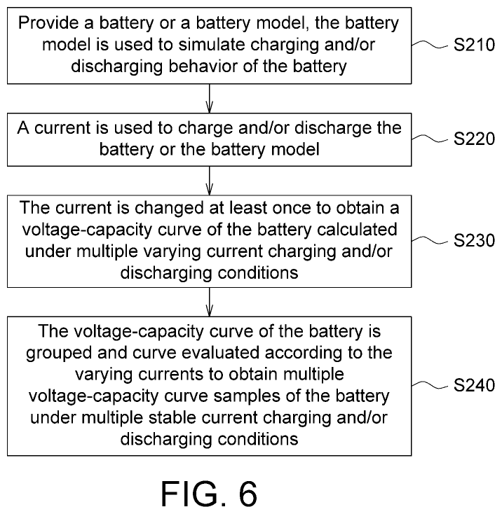

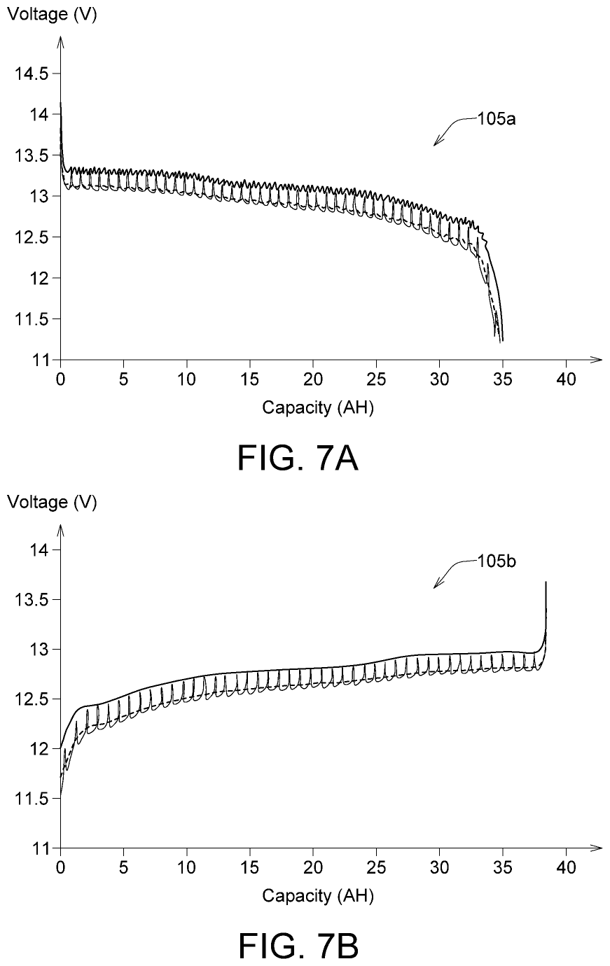

Referring to FIG. 2, the battery measurement system 100 may include a charger/discharger 110, a battery 102 or a battery model 104, a measurement module 120, a reference sample module 130, a comparison module 140 and a resistance calculation module 150. The charger/discharger 110 is used to charge and/or discharge the battery 102 or the battery model 104 to collect samples of charge and/or discharge data of the battery 102. For example, the charger/discharger 110 can input a stable charging current and/or discharging current into the battery 102 and collect charging and/or discharging data of the battery 102 to generate voltage-capacity curve samples 106a and 106b under stable current charging and/or discharging conditions (see FIGS. 8A and 8B). In addition, the charger/discharger 110 can also input various varying charging and/or discharging currents into the battery 102, and collect charging and/or discharging data of the battery 102 to generate voltage-capacity curves 105a and 105b under various varying current charging and/or discharging conditions (see FIGS. 7A and 7B). The voltage-capacity curves 105a and 105b under various varying current charging and/or discharging can be subjected to current grouping and curve evaluation to obtain multiple voltage-capacity curve samples 106a and 106b under multiple stable current charging and/or discharging conditions. For current grouping and curve evaluation, please refer to the description in FIG. 6.

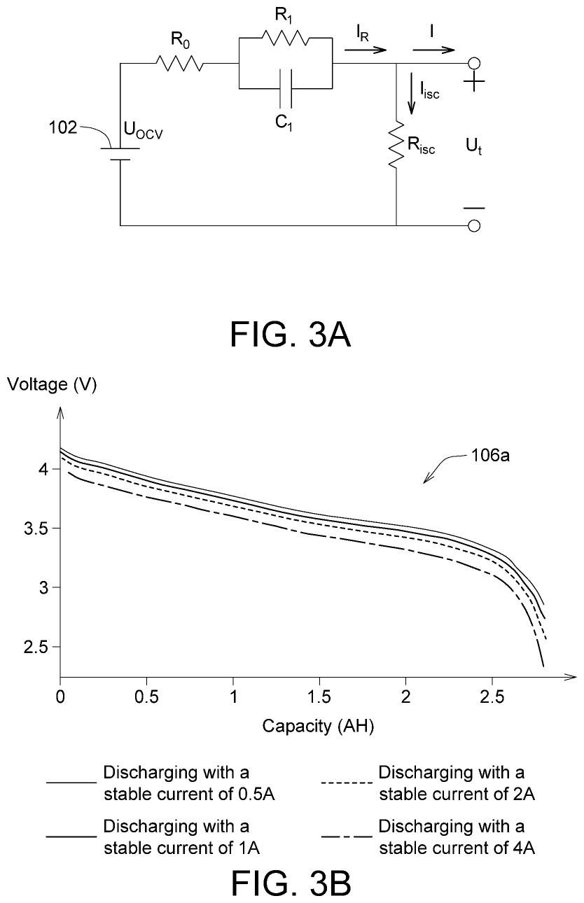

The battery model 104 is used to simulate the charging and/or discharging behavior of the battery 102. The battery model 104 can be a resistor-capacitor (RC) equivalent circuit 104a (see FIG. 3A) created by a battery simulation tool, and then the charging and/or discharging signals can be input into the battery model 104 to simulate the charging and/or discharging behaviors of the real battery 102 and collect the charging and/or discharging data of the battery model 104 to generate multiple voltage-capacity curve samples 106a and 106b under multiple stable current charging and/or discharging conditions (see FIGS. 8A and 8B). Alternatively, various varying charging and/or discharging signals can be input into the battery model 104, and the charging and/or discharging data of the battery model 104 can be collected to generate voltage-capacity curves 105a, 105b (see FIGS. 7A and 7B) under various varying current charging and/or discharging conditions. The voltage-capacity curves 105a and 105b in this varying state can be subjected to current grouping and curve evaluation to obtain multiple voltage-capacity curve samples 106a and 106b under multiple stable current charging and/or discharging conditions. For current grouping and curve evaluation, please refer to the description in FIG. 6.

For the RC equivalent circuit 104a of the battery model 104, please refer to FIG. 3A. U_{OCV} is the voltage of the battery, R₀ is the internal resistance of the battery, R₁ is the equivalent resistance, C₁ is the equivalent capacitance, I_{R} is the equivalent current, I is the output current of the battery, U_{iSC} is the leakage current of the short circuit in the battery, and R_{iSC} is the leakage resistance of an internal short circuit in a battery, where I−I_{R}=U_{iSC}.

The above-mentioned RC equivalent circuit 104a can be used to input the full charge and/or discharge sequence of the battery 102, and can also be used for calculation in a short period of time, for example, the calculation is made once every 5 seconds. In one embodiment, Uₜ is, for example, the voltage calculated using the RC equivalent circuit formula (1), U_{t_m} is the currently measured output voltage of the battery, when Uₜ−U_{t_m} is greater than a threshold, Formula (2) can be derived from the following RC equivalent circuit formula (1) to calculate the leakage resistance R_{iSC} of the battery.

$${U}_{t} ( SOC , T , {I}_{R} , {R}_{0} , {R}_{1} ) = {U}_{OCV} + {I}_{R} \cdot {R}_{0} + {I}_{R} \cdot {R}_{1} ( 1 - {e}^{- \frac{t}{τ}} ) \qquad ( 1 )$$

$${R}_{iSC} = \frac{{U}_{t \_} m}{I - {I}_{R}} \qquad ( 2 )$$

Referring to FIG. 2, the measurement module 120 is used to measure the charge and/or discharge data of the battery 102 or the battery model 104. The charge and/or discharge data at least include a charging voltage sequence and a charging current sequence and/or a discharge voltage sequence and a discharge current sequence. These sequences of charge and/or discharge data are, for example, the values of the charging voltage and the values of the charging current, and/or the values of the discharging voltage and the values of the discharging current obtained sequentially at a fixed time interval on a time axis. In this embodiment, as long as the charge and/or discharge data of the battery 102 is obtained, the charge and/or discharge performance of the battery 102 can be evaluated through real-time analysis and comparison.

Referring to FIG. 2, the reference sample module 130 is used to store a plurality of voltage-capacity curve samples 106a and 106b of the battery 102 under stable current charging and/or discharging conditions. These voltage-capacity curve samples 106a and 106b can be obtained through the experimental results of the charger/discharger 110 on the battery 102 or the battery model 104, and are pre-stored in the reference sample module 130 for table lookup.

Referring to FIG. 2, the comparison module 140 is used to detect whether the charge and/or discharge data of the battery 102 is normal in real time. For example, in one embodiment, the comparison module 140 can compare whether the charge and/or discharge data 102a of the battery 102 is consistent with at least one reference curve in the plurality of voltage-capacity curve samples 106 under stable current charging and/or discharging conditions. When the charge and/or discharge data of the battery 102 is consistent with the reference curve, indicating that the battery 102 is normal. When the charge and/or discharge data 102a of the battery 102 is inconsistent with the reference curve, indicating that the battery 102 is abnormal. For example, in FIG. 3B, when the battery 102 is discharged with a stable current (for example, 2 Amps), but the discharge data of the battery 102 is inconsistent with the voltage-capacity curve sample 106a under a stable current discharging condition (for example, 2 Amps), it means that a leakage current may be generated due to an internal short circuit in the battery 102, so that the discharge data of the battery 102 deviates from the voltage-capacity curve sample 106a under a stable current discharging condition (for example, 2 Amps).

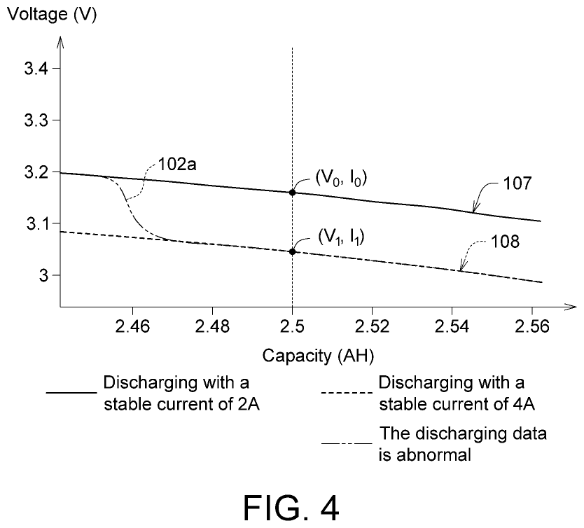

Referring to FIG. 2, the resistance calculation module 150 is used to calculate the voltage and capacity of the battery 102 and the reference curve under the same charge and/or discharge current, and a current difference is estimated based on the voltage difference between the charge and/or discharge data of the battery 102 and the reference curve under a same charge and/or discharge current and a same capacity. For example, in FIGS. 3B and 4, the voltage and capacity of the voltage-capacity curve sample 106a (i.e., the reference curve) and the voltage and capacity of the battery 102 under a stable current discharging condition (for example, 2 Amps) are calculated. When the discharge voltage of the battery 102 deviates from the voltage-capacity curve sample 106a under the stable current discharging condition (for example, 2 Amps), the resistance calculation module 150 calculates the current difference (I₁−I₀) based on the voltage difference (V₀−V₁) between the battery 102 and the reference curve under a same capacity (for example, 2.5 amp-hour capacity). When there is no reference curve under the same current for comparison, the current difference (I₁−I₀) can be calculated by interpolation.

In this embodiment, the voltage difference is, for example, the difference between the normal discharge voltage V₀ and the abnormal discharge voltage V₁, and the current difference is, for example, the difference between the abnormal discharge current I₁ and the normal discharge current I₀. If the current difference is greater than 0, it means that the leakage current U_{iSC} may be generated inside the battery 102 due to an internal short circuit; if the current difference is less than 0, it means that the discharge current may be reduced due to aging or an increase in internal resistance in the battery 102. Next, the resistance calculation module 150 can calculate the leakage resistance R_{iSC} of the battery 102 according to Ohm's law. According to Ohm's law

$${R}_{isc} = \frac{V}{{I}_{isc}} ,$$

the leakage resistance R_{iSC} of the battery 102 is equal to the voltage of the battery 102 divided by the current difference (I₁−I₀). For example, in FIG. 4, when the battery 102 is discharged with a load current of 2 A until the capacity is 2.5 AH, the correct voltage value should be 3.16V, but the actual measured voltage value is 3.05V. Based on the voltage difference, the current difference is calculated between the voltage-capacity curve sample 107 of the discharge current of 2 A corresponding to the voltage of 3.16V and the voltage-capacity curve sample 108 of the discharge current of 4 A corresponding to the measured voltage of 3.05V under the same capacity (2.5 AH), that is, 4 A−2 A=2 A, it means that the leakage current is 2 A. From this result, the leakage resistance R_{iSC} of the battery 102 can be calculated to be 3.05/2=1.525 ohms. When there is no reference curve under the same current for comparison, the current difference of the battery 102 can be calculated by interpolation, and then the leakage resistance R_{iSC} can be calculated.

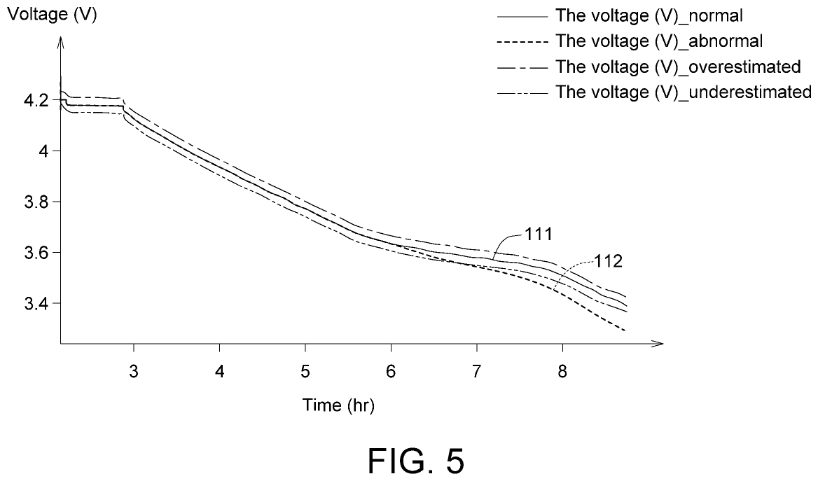

Referring to FIG. 5, a schematic diagram in which the measured voltage curve 112 of the battery 102 deviates from the normal discharge reference curve 111 is illustrated. It can be seen from the above Ohm's law calculation formula that under constant current, voltage and resistance are positively correlated. If the battery 102 has a leakage current U_{iSC} caused by the internal short circuit, it will cause the measured voltage to deviate from the normal discharge reference curve 111, thereby affecting the battery 102 over-discharge. The battery measurement system 100 of this embodiment can initiate troubleshooting based on the leakage resistance of the battery 102 to avoid dangers caused by over-charging or over-discharging the battery 102.

Referring to FIGS. 6 to 8, FIG. 6 is a schematic diagram of a method for establishing reference samples of the battery 102 according to an embodiment of the present disclosure. FIGS. 7A and 7B respectively are schematic diagrams of voltage-capacity curves 105a and 105b of the battery 102 under various varying current charging and/or discharging conditions in FIG. 6. FIGS. 8A and 8B are respectively schematic diagrams of multiple voltage-capacity curves 106a and 106b under multiple stable currents obtained through grouping and curve evaluation under various varying currents charging and/or discharging conditions.

The method for establishing reference samples of a battery 102 includes the following steps. In step S210, a battery 102 or a battery model 104 is provided. The battery model 104 is used to simulate the charging and/or discharging behavior of the battery 102. In step S220, a current is used to charge and/or discharge the battery 102 or the battery model 104. In step S230, the current is changed at least once to obtain a voltage-capacity curve of the battery 102 calculated under multiple varying current charging and/or discharging conditions. In step S240, the voltage-capacity curve of the battery 102 is grouped and curve evaluated according to the varying currents to obtain multiple voltage-capacity curve samples of the battery 102 under multiple stable current charging and/or discharging conditions.

First, in step S210, providing the battery model 104 includes performing dynamic current control on the battery 102 to generate a voltage-time sequence, and then using the RC equivalent circuit formula to calculate the parameters of its circuit components to establish the RC equivalent circuit 104a of the battery model 104 (see FIG. 3A). In addition, in step S220, charging and/or discharging the battery 102 or the battery model 104 with a current includes inputting multiple varying current sequences into the RC equivalent circuit 104a of the battery model 104 to simultaneously generate the voltage-capacity curves 105a and 105b under multiple varying currents charging and/or discharging conditions, as shown in FIGS. 7A and 7B. The varying current sequences are, for example, currents of 0.5 A, 1 A, 2 A, 4 A and more. In addition, in step S230, grouping and curve evaluation of the voltage-capacity curve of the battery 102 includes grouping by the inputted multiple varying current sequences, discretizing the voltage-capacity of the battery 102 into multiple voltage-capacity sub-sequences, and each of the voltage-capacity sub-sequences corresponds to a stable current, and then the voltage-capacity sub-sequences with the same current are respectively fitted to a curve according to a curve evaluation to obtain multiple voltage-capacity curve samples 106a and 106b under multiple stable current charging and/or discharging conditions, as shown in FIGS. 8A and 8B.

Since the above-mentioned grouping and curve evaluation only require one charge and/or discharge process (for example, one time for about 8 hours and 25 minutes), compared with the standard charge and/or discharge process to be carried out four times for about 35 hours to charge and/or discharge battery, and each time with different currents (for example, currents of 0.5 A, 1 A, 2 A and 4 A). This method in the disclosure can significantly reduce the time for generating the charge and/or discharge curve.

The calculation system and the method for calculating a resistance of an internal short circuit in a battery and the method for establishing battery reference samples in the above embodiments of the present disclosure have the following characteristics: (1) a battery model is established to simulate battery charging and/or discharging behaviors; (2) varying currents and stable currents are used to generate multiple voltage-capacity curve samples; and (3) whether the battery is abnormal is determined and the leakage resistance is calculated based on the voltage-capacity curve.

It will be apparent to those skilled in the art that various modifications and variations can be made to the disclosed embodiments. It is intended that the specification and examples be considered as exemplars only, with a true scope of the disclosure being indicated by the following claims and their equivalents.

What is claimed is:

1. A method for calculating a resistance of an internal short circuit in a battery, comprising:
obtaining a plurality of voltage-capacity curve samples of a battery under a plurality of stable current charging and/or discharging conditions;
measuring charge and/or discharge data of the battery, and the charge and/or discharge data at least comprises a charging voltage sequence and a charging current sequence, and/or a discharge voltage sequence and a discharge current sequence;
comparing the charge and/or discharge data of the battery with at least one reference curve in the voltage-capacity curve samples to determine whether the battery is charged and/or discharged normally; and
when the charge and/or discharge data of the battery deviates from the reference curve, a leakage current and a leakage resistance of the battery are calculated.

2. The method according to claim 1, wherein calculating the leakage resistance of the battery comprises a current difference is estimated based on a voltage difference between the charge and/or discharge data of the battery and the reference curve under a same charge and/or discharge current and reaching a same capacity and the leakage resistance of the battery is calculate based on Ohm's law.

3. The method according to claim 2, wherein the leakage resistance of the battery is equal to a voltage of the battery divided by the current difference.

4. A method for establishing reference samples of a battery, comprising:
providing a battery or a battery model, the battery model is configured to simulate charging and/or discharging behaviors of the battery;
charging and/or discharging the battery or the battery model with a current;
changing the current at least once to obtain a voltage-capacity curve of the battery under a plurality of varying current charge and/or discharge conditions; and
wherein the voltage-capacity curve of the battery is grouped and curve evaluated based on the varying currents to obtain a plurality voltage-capacity curve samples of the battery under a plurality of stable currents charging and/or discharging conditions.

5. The method according to claim 4, wherein providing the battery model comprises performing a dynamic current control on the battery, and using a resistor-capacitor (RC) equivalent circuit formula to calculate parameters of circuit components to establish a RC equivalent circuit of the battery model.

6. The method according to claim 5, wherein charging and/or discharging the battery or the battery model with a current comprises inputting a plurality of varying current sequences into the RC equivalent circuit to simultaneously generate the voltage-capacity curve under the plurality varying currents charging and/or discharging conditions.

7. The method according to claim 6, wherein grouping and curve evaluation of the voltage-capacity curve of the battery comprises grouping by the inputted plurality of varying current sequences.

8. A measurement system for calculating a resistance of an internal short circuit in a battery, comprising:
a measurement module configured to measure charge and/or discharge data of a battery or a battery model, the charge and/or discharge data at least comprises a charging voltage sequence and a charging current sequence, and/or a discharge voltage sequence and a discharge current sequence;
a reference sample module for storing a plurality voltage-capacity curve samples of the battery under stable current charging and/or discharging conditions;
a comparison module for comparing whether the charge and/or discharge data of the battery is consistent with at least one reference curve in the plurality of voltage-capacity curve samples under stable current charging and/or discharging conditions; and
a resistance calculation module, wherein when the charge and/or discharge data of the battery deviates from the reference curve, the resistance calculation module calculates a leakage current and a leakage resistance of the battery.

9. The measurement system according to claim 8, wherein the resistance calculation module estimates a current difference based on a voltage difference between the charge and/or discharge data of the battery and the reference curve under a same charge and/or discharge current and reaching a same capacity to calculate the leakage resistance of the battery based on Ohm's law.

10. The measurement system according to claim 9, wherein the leakage resistance of the battery is equal to a voltage of the battery divided by the current difference.

11. The measurement system according to claim 8, further comprising a charger/discharger for charging and/or discharging the battery, and collecting the charge and/or discharge data of the battery, so as to generate the plurality voltage-capacity curve samples of the battery under stable current charging and/or discharging conditions.

12. The measurement system according to claim 8, wherein the battery model establishes a RC equivalent circuit through a battery simulation tool, and then inputs charge and/or discharge signals into the RC equivalent circuit to simulate the charging and/or discharging behavior of the battery, and the charging and/or discharging data of the battery model is collected to generate the plurality of voltage-capacity curve samples under stable current charging and/or discharging conditions.
